(19) United States
(12) Patent Application Publication
(10) Pub. No.: US 2010/0193010 A1
(43) Pub. Date: Aug. 5, 2010

(54) REFLECTOR AND SYSTEM FOR PHOTOVOLTAIC POWER GENERATION

(76) Inventor: David N. Wells, Silver Spring, MD (US)

Correspondence Address: LAUBSCHER & LAUBSCHER, P.C., 1160 SPA ROAD, SUITE 2B, ANNAPOLIS, MD, 21403, US

(21) Appl. No.: 12/605,423

(22) Filed: Oct. 26, 2009

Related U.S. Application Data
(63) Continuation-in-part of application No. 12/388,885, filed on Feb. 19, 2009.
(60) Provisional application No. 61/149,201, filed on Feb. 2, 2009.

(51) Int. Cl. H01L 31/052; G02B 5/08; G02B 5/22

(52) U.S. Cl. 136/246; 359/883; 359/360; 359/359

(57) ABSTRACT

A reflector for photovoltaic power generation is characterized by the use of a color coating on the surface of the reflector material which is stable to ultraviolet light. The reflector includes a substrate and a layer of high purity aluminum on the substrate. The aluminum layer is anodized and coated with a gold dye so that the reflector has a reflectivity which is high for long wave, near infrared, and red to green light, moderate for blue light, and low for ultraviolet light. When such a reflector is arranged adjacent to a photovoltaic panel, it reflects additional sunlight onto the panel to increase the electrical output of the panel without damaging the solar collector material of the panel.

This application is a continuation-in-part of U.S. application Ser. No. 12/388,885 filed Feb. 19, 2009 which claims the benefit of U.S. Provisional Application No. 61/149,201 filed Feb. 2, 2009.

### BACKGROUND OF THE INVENTION

Solar power systems which generate electricity from sunlight typically incorporate flat photovoltaic panels which are arranged to capture sunlight. Such panels may be arranged along a north-south axis or be mounted for movement to track either a polar axis or two axes.

In order to maximize the sunlight directed against the panels, mirrors are often used to reflect additional rays from the sun toward the panel at different angles. The use of mirrors enhances the output power of a photovoltaic panel because a greater amount of sunlight is directed against the panel than against a panel without any reflectors. For example, in a polar axis tracking device, a centrally arranged mirror directs sunlight to photovoltaic panels on either side.

One drawback to solar power systems, particularly those used in high temperature environments, is that excessive heat and ultraviolet rays from the sunlight damage the photovoltaic panels. The heat is generated both from the environment in which the panel is located as well as from the blue range of light within the sun's rays. When the surface of the panel is damaged, its ability to absorb sunlight is impeded, thereby reducing its electrical output.

Another drawback to conventional solar power systems is distortion created by mirrors that are not uniform. Ripples and other non-uniformities in the reflector surface of the mirror are the result of a variety of physical defects, most of which arise during the formation of the reflector material. These defects can be directly on the reflector surface or are the result of imperfections in the adhesive backing layer used to connect the reflector material to a substrate. The distortion resulting from such ripples produces areas of increased temperature on the photovoltaic panel surface which damage the surface over time.

The present invention was developed in order to overcome these and other drawbacks of prior solar power systems by providing an improved reflector which has a uniform reflective surface and which reduces ultraviolet light reflected toward a photovoltaic panel. In addition, the improved reflector reduces the blue light reflected toward the panel, thereby reducing the heat generated on the panel.

### SUMMARY OF THE INVENTION

The invention relates to an improved reflector or mirror for use in connection with a photovoltaic cell of a solar power generation system. The reflector is a composite structure including a substrate on which a reflector material is arranged. The reflector material may be a metal coated with a color material or a synthetic plastic film doped with a color material. The color material is stable to ultraviolet light. Accordingly, sunlight directed from the reflector onto a photovoltaic cell or panel does not contain ultraviolet light and thus does not damage the panel.

According to a preferred embodiment, the reflector material comprises high purity aluminum and the color material comprises a gold color dye to produce a reflector having a high reflectivity for long wave, near infra red and red to green light, moderate reflectivity for blue light, and low reflectivity for ultraviolet light. In addition, a similar aluminum reflector coated with color material may be provided on the opposite surface of the substrate so that the reflector is reversible. After the coated reflector on one surface of the substrate has degraded over time, the reflector can be reversed to position the opposite surface thereof to direct sunlight onto the photovoltaic cell or panel.

A clear protective coating is applied to the reflector material and a second layer of aluminum is preferably applied to the rear of the substrate. In addition, a corrugated metal layer is provided between the substrate and the second layer of reflective aluminum. This preferred structure eliminates imperfections or ripples in the surface of the reflector material so that uniform rays are reflected onto the photovoltaic panel.

The substrate can be formed of any suitable rigid material including metal, polymer, or wood. Moreover, the reflector may be formed with a concave configuration to concentrate reflected sunlight on the panel.

The reflector is preferably mounted in spaced relation adjacent and at an angle to a photovoltaic panel. More particularly, the reflector is mounted on a support which is capable of adjusting the angular position of the reflector relative to the panel. The panel is preferably positioned relative to a north-south axis and the reflector is adjusted at various times throughout the day, throughout the month, and/or throughout the year in accordance with the position of the sun in the sky so that the maximum amount of sunlight can be captured and reflected to the panel.

### BRIEF DESCRIPTION OF THE FIGURES

Other objects and advantages of the invention will become apparent from a study of the following specification when viewed in the light of the accompanying drawing, in which:

FIG. 1 is a perspective view of an array of photovoltaic panels arranged along a north-south axis according to the prior art;

FIG. 2 is a side view of a photovoltaic panel and reflector of a solar energy system according to the invention;

FIGS. 3-5 are sectional views of different embodiments, respectively, of the reflector according to the invention;

FIG. 6 is a partially cut away perspective view of a further embodiment of the reflector according to the invention;

FIG. 7 is a diagram of the method steps for manufacturing a preferred reflector material for the reflector of FIG. 2;

FIG. 8 is a diagram of the method steps for manufacturing an alternate reflector material for the reflector of FIG. 2;

FIG. 9 is a schematic view of a photovoltaic panel and a concave reflector according to the invention;

FIG. 10 is a detailed side view showing the mounting arrangement for a photovoltaic panel and reflector according to the invention;

FIGS. 11 and 12 are side views of an array of photovoltaic panels and reflectors in first and second positions, respectively;

FIG. 13 is a graph illustrating the integrated thermal impact on a photovoltaic panel at various wavelengths of light from the reflector according to the invention;

FIGS. 14 and 15 are graphs showing the damage over time from ultraviolet rays from a gold colored reflector and a silver colored reflector, respectively;

FIG. 16 is a sectional view of a further embodiment of a reflector panel according to the invention;

FIG. 17 is a perspective view showing the arrangement of layers of wood for the reflector of FIG. 16; and

FIG. 18 is a detailed sectional view of the reflector of FIG. 16 including a seal at the edge of the reflector.

### DETAILED DESCRIPTION

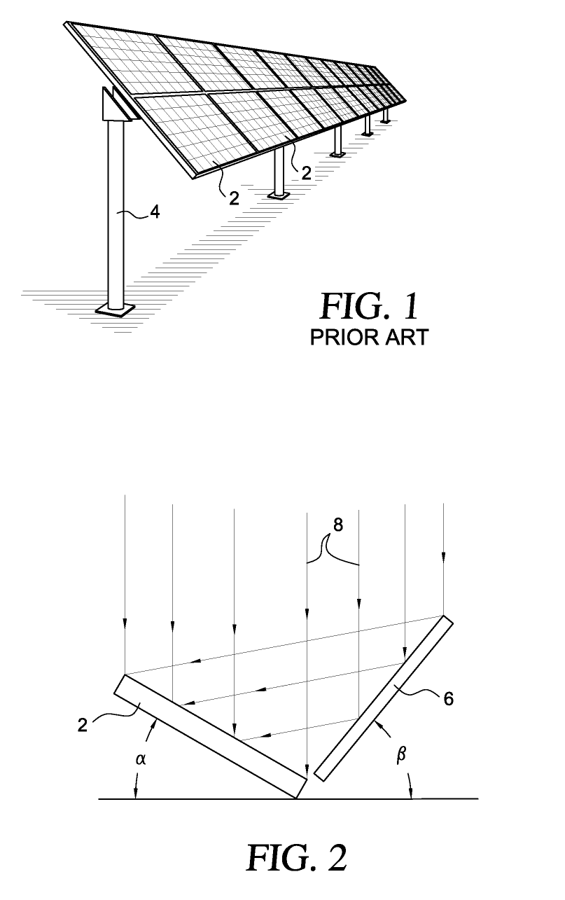

Solar power systems utilized photovoltaic panels to capture solar energy from sunlight and convert it to electricity. FIG. 1 shows an array of flat photovoltaic panels 2 mounted in side-by-side relation on a support structure 4 as is known in the art. The array is arranged along a north-south axis in order for the panels to capture sunlight at an optimum angle. Other arrangements of panels including polar axis and two-axis tracking systems, not shown, are also known in the art.

Referring now to FIG. 2, the preferred embodiment of the invention will be described. As shown therein, a reflector or mirror 6 is arranged adjacent to a photovoltaic panel 4 to direct additional sunlight 8 against the panel to increase the electrical output of the panel. The panel is arranged at an angle α relative to the ground and the reflector is arranged at an angle β to redirect sunlight against the panel as shown. The angle α is between 10° and 35° and preferably between 20° and 30°, depending on the latitude where the solar power system is mounted. The angle β is between 40° and 60° and preferably between 45° and 55° to provide boosted sunlight to the panel while minimizing the effects of dirt or other contaminants on the reflector.

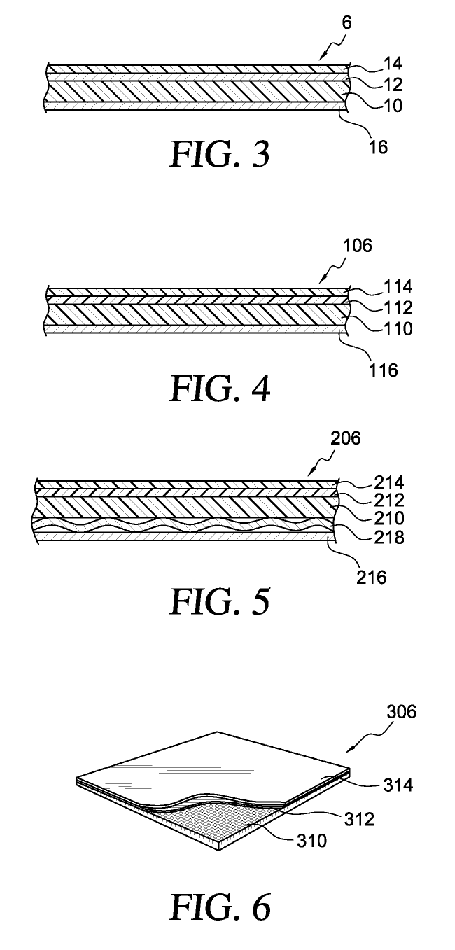

The structure of the reflector 6 will be described with reference to FIGS. 3-8. The reflector is a composite structure of different layers which are sandwiched together. In the embodiment of FIG. 3, the reflector 6 includes a rigid substrate 10 formed of synthetic plastic material such as a polymer. On the upper surface of the substrate is a layer of reflective material 12. The preferred reflector material may be a metallic material and according to the preferred embodiment, the material is aluminum. Other suitable metals including silver may be used for the reflective material. A characterizing feature of the invention is that the reflective material is coated with a color material which is stable to ultraviolet light. The preferred color is gold which can be provided in different shades as will be developed below.

A protective coating layer 14 is provided on the layer of reflective material. It is a thin clear coating which protects the reflective surface from contaminants without diminishing its the reflective capacity. Suitable materials for the coating layer include inorganic materials such as a sol-gel overcoat or a fluorocarbon overcoat. In addition, the bottom surface of the substrate 10 can be provided with a layer 16 of reflective material such as metal including silver or aluminum.

FIG. 4 shows a reflector 106 including a substrate 110, a reflector layer 112, a coating layer 114, and a rear reflector layer 116. In this embodiment, the substrate 110 is formed of a metal material and the reflector layer 112 is formed of a synthetic plastic material such as polymer which has been doped with an organic dye.

In FIG. 5, another embodiment of the reflector 206 is shown including a metallic substrate 210, a layer of metallic reflector material 212, a coating layer 214, and a metallic rear reflector layer 216. Between the substrate and the rear layer is provided a layer of corrugated metal material 218 which increases the structural strength of the reflector.

FIG. 6 illustrates a further embodiment of a reflector 306 in which the substrate 310 has an open, honeycomb structure covered by a reflective layer 312 and a cover layer 314. The honeycomb substrate is formed of synthetic plastic material an provide a high degree of rigidity to the reflector.

It will be appreciated that reflectors may be formed with any combination of the materials for the layers described in FIGS. 3-5. The layers may be joined by adhesive or other techniques such as vapor deposition as is known in the art.

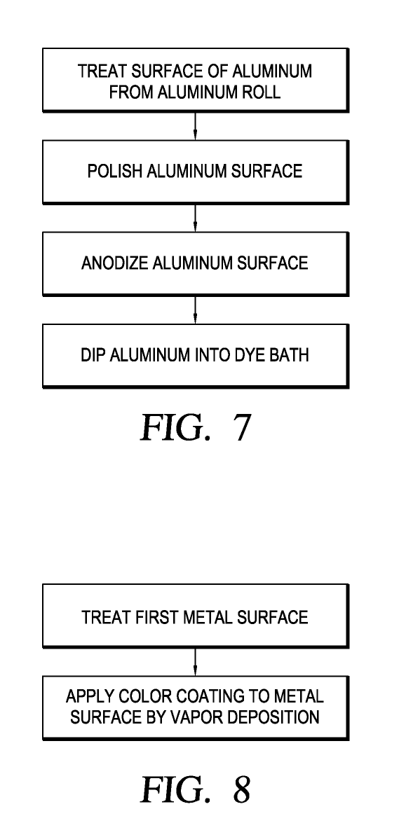

The preferred reflective material for the reflectors according to the invention is high purity aluminum with a gold coating. The formation of the reflective material will be described. The surface is made by a continuous process using thin aluminum that can be formed using a high speed roll-to-roll foil coating process. The process may include non-vacuum anodizing and dyeing processes such as rolling/unrolling continuous anodized and dye process or a vacuum coil process suing chemical or plasma vapor formed aluminum. A suitable inexpensive process for producing a spectrally selective reflective layer is known as ferric ammonium oxalate (FAO) or ferric sodium oxalate (FSO) aluminum anodize and dye. Referring to FIG. 7, in a continuous roll process, aluminum is fed from a roll and its surface is treated to provide a smooth surface. The surface is next polished by physical and chemical abrasion to remove any remaining impurities. The surface is then anodized and the aluminum is dipped into a dye bath containing the FAO or FSO dye. These dyes produce a surface coloration of the aluminum that is inorganic in nature and highly stable to ultraviolet light. The resulting surface has the desired spectral properties and stability for maximum efficiency and long life in the reflector.

Another process for producing the reflector material is shown in FIG. 8. A metal material such as silver undergoes surface treatment to remove imperfections therefrom and provide a smooth surface. The color coating, preferably gold, is then applied to the metal surface by vapor deposition.

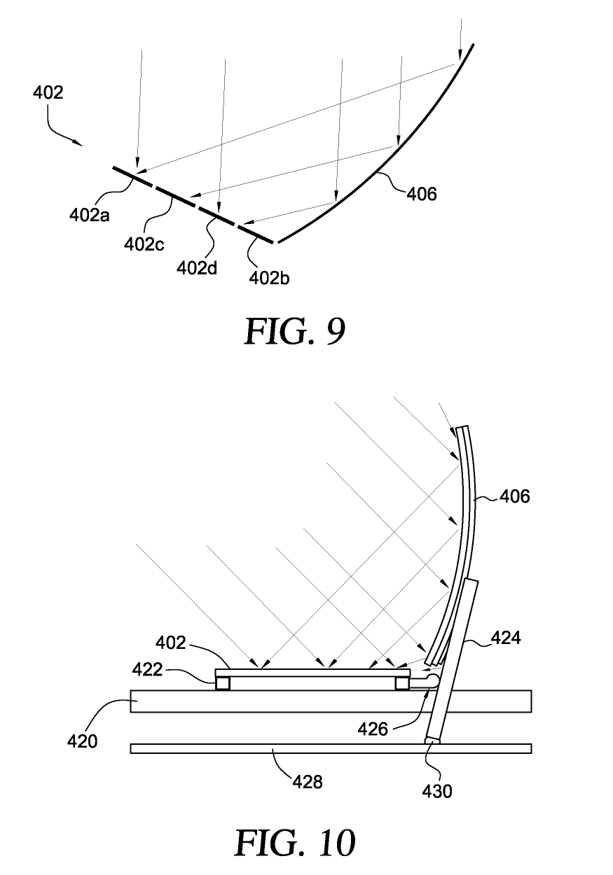

Turning now to FIG. 9, there is shown a reflector 406 having a concave configuration. With planar reflectors, the upper and lower edges of the photovoltaic panel 402 do not receive as much light as the central portion of the panel. Thus, the upper panel portion 402a and the lower panel portion 402b receive less light than the central portions 402c and 402d of the panel. By providing a concave surface for the reflector, the reflected sunlight is more easily distributed across the panel surface.

FIG. 10 is a conceptual representation for mounting a reflector 406 according to the invention relative to a photovoltaic panel 402. The panel is secured to a support bar 420 via mounting posts 422. An arm 424 pivotally connects the reflector relative to the panel. More particularly, the arm is connected with a mounting post of the panel via an upper ball joint 426. The arm is further connected with a push rod 428 via a lower ball joint 430. Displacement of the push rod changes the angle of the reflector relative to the panel so that sunlight striking the reflector is direct to the panel. An air gap 432 is provided between the reflector and the photovoltaic panel to allow the flow of air around the panel which helps to cool the panel and improve its efficiency.

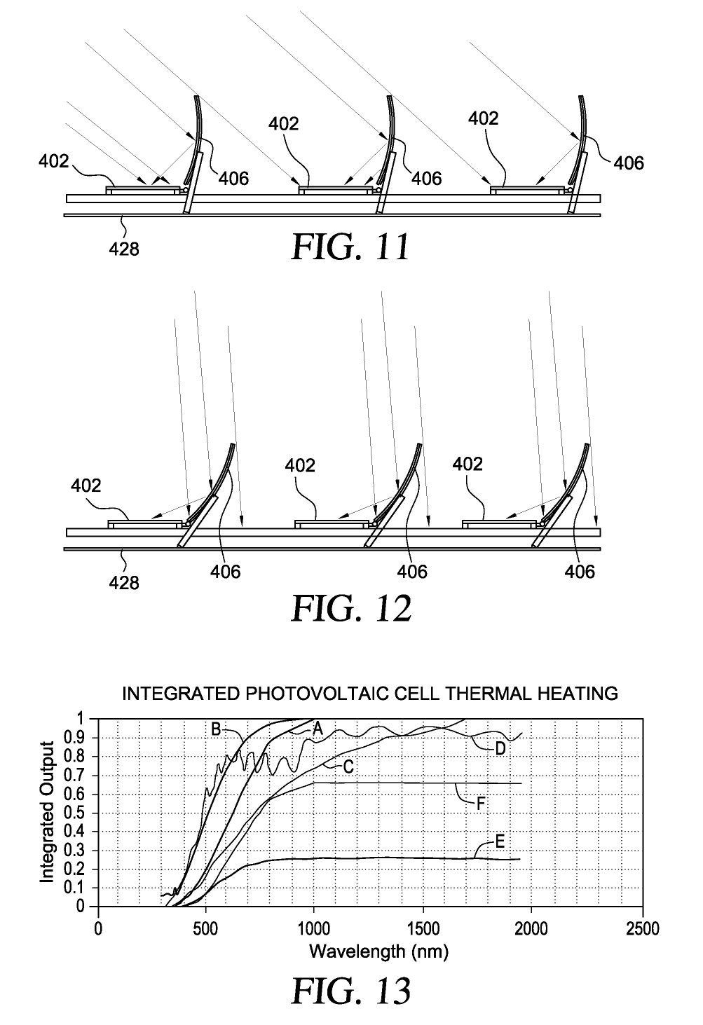

As the sun's angle of incidence varies over the day or year, the angle of the reflector 406 is changed, while the photovoltaic panel 402 remains fixed. This is shown in FIGS. 11 and 12 which represent an array of panels and reflectors arranged adjacent to one another to define a series of solar collectors in a solar energy system. Referring to FIG. 11, virtually all of the sunlight strikes the photovoltaic panels, either directly or reflected from the reflectors, when the sunlight has its greatest angle of incidence. FIG. 12 represents a near normal solar incidence angle. In this figure, the reflectors are moved by operating the push rod 428. The range of motion of the reflectors is up to 60° relative to the photovoltaic panels. All light that hits the reflectors is directed at the photovoltaic panels. However, some of the incident sunlight does not hit either the panels or the reflectors. This sunlight is uncollected and hits the ground.

The advantage of the arrangement shown in FIGS. 11 and 12 is that the sunlight level hitting the photovoltaic panels is kept uniform over the full operational year. This design feature results in optimum usage of expensive solar photovoltaic panels at the relatively small cost of a slight amount of missed sunlight during the summer months. Another benefit to the arrangement shown in FIGS. 11 and 12 is that the reflectors are resistant to hail damage because their surfaces are nearly vertical. In addition, wind loading is in a direction that is perpendicular to the plane of the reflectors. The force direction depends on the angle of the mirrors, but this angle is such that the perpendicular to the mirrors is in a direction that is parallel to the main support post, i.e. north-south. This is the strongest axis of the support structure, so the structural forces are low and no additional stiffening structures are needed.

Ultraviolet light and excessive heat will damage or destroy a photovoltaic cell. The reflector according to the invention is designed to remove prevent ultraviolet and blue light from striking the panel to keep the panel cool.

One key aspect of an efficient reflector other than eliminating ultraviolet damage and overheating due to blue light content relates to the control of uniformity of the light flux. Distortion in reflection is due to the lack of uniformity of the reflector surface. Ripples in the surface can be introduced by a variety of physical defects present due to such things as ripples produced in a roll forming aluminum process. Historically, the use of thin plastic films laminated to thick aluminum substrates has been tried, but serious problems exist. For one, the thin plastic film on aluminum approach relies on an adhesive backing layer. Discontinuities in the adhesive backer film create a severe ripple problem.

Recently, high precision reflector panels have been designed with a thin aluminum reflector layer which is first straightened and then bonded in a sandwich to a polymer, forming a very rigid and very flat composite panel. The tests on this material show it to be vastly flatter than previous designs, and void of any hot spot forming non-uniformities.

Ultraviolet light of the solar spectrum, which is light from 320 nanometers to 400 nanometers, damages photovoltaic panel surfaces by reacting with any water in the surface, thereby forming free radicals and hydrogen. By blocking the ultraviolet light with a gold-tint FAO dye, the surface of the photovoltaic panel has an improved lifespan.

Ultraviolet light damages not only the photovoltaic panel, but also the aluminum film of the reflector. However, by anodizing and FAO dyeing the aluminum reflector material, damage to the reflector layer is avoided. Moreover, FAO dyed aluminum has a substantially lower ultraviolet reflectivity than the non-dyed aluminum since the FAO coating absorbs the ultraviolet light in a manner which does not cause a chemical reaction with the aluminum.

A photovoltaic panel may use a variety of solar cells including crystal silicon, amorphous silicon, multi-crystal silicon, and copper-indium-gallium-selenium (CIGS) cells. The typical photovoltaic panel with which the reflector according to the invention is use utilizes either crystal silicon or CIGS cells. The relative response of silicon peaks at 900 nanometers. Thus, the device is most efficient at this wavelength, with little heat being produced. At 600-700 nanometers (deep red light), the response is down to about 80%, so only a modest amount of heating is caused by the red light. For 500-600 nanometer or green to orange light, efficiency is only about 60% as compared to 900 nanometers. For blue light at 400-500 nanometers, the spectral response of the silicon cell is around 40% from the response at 900 nanometers. The silicon cell produces less than half as much electric power for blue light as it does for 900 nanometer light, and about 2 to 3 times more heating per watt of input solar power. The CIGS cell is similar to the crystal silicon cell but has a slightly improved response to light in the 900 to 1100 nanometer infrared range.

FIG. 13 is a graphical representation of integrated photovoltaic cell thermal heating due to incoming sunlight and due to light reflected by a gold coated reflector according to the invention. It shows the integrated total power A, integrated heating effect B due to excess photon energy and the power content of solar incoming light C as the wavelength is varied from ultraviolet to infra-red. This graph is obtained by taking the data relating to incoming sunlight spectra and the crystalline silicon cell photovoltaic response, multiplying the incoming sunlight spectra by the crystalline silicon response, and integrating this product from the ultraviolet wavelength to a given wavelength value shown. Integrating the data from ultraviolet wavelength to the far infrared wavelength results in a total value of 1.0. As the graph shows, the silicon solar cell integrated electric power A reaches 1.0 by integrating over the range of 350 nanometers to 1000 nanometers. No additional electric power output is produced for wavelengths past 1000 nanometers. Also shown on the graph is a line B representing solar cell heating. This line is produced by multiplying the incoming sunlight solar content by the value of one minus the response of the solar cell. The value of the solar heating reaches a value of about 0.5 or 50% for a solar wavelength of 500 nanometers. Stated another way, half of the heating of the cell is due to light from the ultra-violet to the blue. However, the solar cell integrated electric power A is only at 20% for this wavelength. Stated yet another way, if all light from ultraviolet to blue is rejected, the electric power output of the photovoltaic cell would drop by 20%, and the heating rate of the solar photovoltaic cell would be dropped by half.

The reflector according to the invention includes a reflective surface that removes unwanted and poorly utilized colored light, thereby reducing heating and sacrificing some power, and reflects instead the more useful colors of light such as orange, yellow, red, and infrared which produce electric power efficiently without heating the cell.

More specifically, the reflective surface of the reflector has a reflectivity value that is low in the ultraviolet (reflectivity of about 0 to 30%), moderate for blue light from 400 to 500 nanometers (reflectivity of about 20 to 50%), relatively high for green to orange light (about 60 to 80% reflectivity) and high for red and infrared light (reflectivity of 80-100%). Surfaces with this type of reflectivity appear to the human observer as being the color of the metal gold.

By providing a surface of this spectral reflective characteristic and then applying this material in a reflector for photovoltaic applications, the output power of a photovoltaic panel can be increased without causing excessive heating.

Referring again to FIG. 13, the reflective surface of a gold-tinted aluminum reflector or mirror is shown by line D. This material has the desired low reflectivity in ultraviolet, moderate reflectivity in blue, higher reflectivity in orange, and high red and infrared reflectivity. When this reflector is used, the resulting heating effect is plotted as line E and is shown to reach a value of about 0.26, indicating that the heating effect on the photovoltaic panel is about 26% as great in comparison to using a perfectly reflective mirror. On the other hand, the electric power produced by the gold tinted reflector, plotted as the line F, shows that the output electric power produced by the panel reaches a value of about 66% of the value that would have been obtained by using a perfect reflector. This is very desirable since the problems of over-heating and ageing can be dramatically reduced. With the reflector according to the invention, photovoltaic panels can be safely used and their electric power output can be increased without shortening the solar photovoltaic panel life.

The reflector according to the invention has good reflectivity in the mid-infrared range which is helpful in cooling the photovoltaic panel. When a solar photovoltaic panel is placed in the sun, it absorbs light and heats up. The solar panel is most efficient when it is cool. Normally, a photovoltaic panel keeps cool by radiation cooling, e.g. by emitting mid and long-wave infrared, and by convective cooling in which heat is lost to the air surrounding the panel. On a sunny and cloud-free day, the photovoltaic panel emits to its surroundings, and the apparent temperature of its surroundings becomes an important parameter. If the surroundings are warm, the panel cannot shed heat as effectively. The sky appears as a radiator with a temperature from under 0° C. to around 20° C., depending on the level of clouds and haze. To keep the photovoltaic panel coolest, it is best if the panel is exposed the coolest possible surroundings. Unfortunately, in the past, back-silvered glass reflectors were used as solar boost mirrors. The back-silvered glass reflector is virtually black in the near infrared wavelengths of light, so infrared light emitted by the panel simply stops at the glass reflector surface and is absorbed, causing the glass to heat up and re-radiate heat back to the panel.

A more advantageous mirror would have moderate reflectivity in the mid-IR wavelength range. The dyed anodized aluminum reflector according to the invention demonstrates fairly good mid-infrared reflectivity. Gold tinted aluminum reflectors have moderate reflectivity in the infrared, so the photovoltaic panel is exposed to the cold sky surrounding it, rather than the warm surface of the reflector. By way of example, with a sky temperature of 0° C., the gold tint reflector, whose reflectivity is about 50% for mid infrared, detects a sky temperature of around 10° C. even though the mirror is at room temperature.

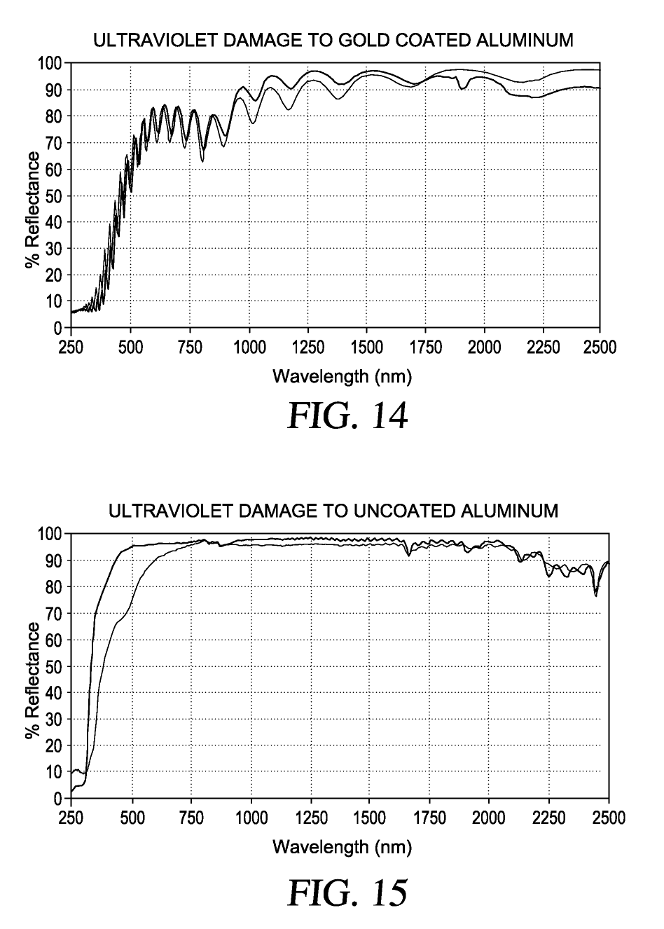

As set forth above, ultraviolet light damages the surface of photovoltaic panels. FIGS. 14 and 15 show how such light damages not only the photovoltaic panels but also the aluminum film of the reflector. These figures show the damage over time to a gold coated thin aluminum film reflector (FIG. 14) and to a thin aluminum film reflector without a gold coating layer (FIG. 15). In both figures, two lines are plotted: the original reflectivity of the panel (upper line) and the reflectivity of the panel after three months of accelerated ultraviolet exposure testing. The upper FAO-dyed gold-tinted panel shows virtually no change in the test. The panel that did not have the FAO dye changed in reflectivity after the test. Thus, the FAO dye also improves the stability of the aluminum reflecting layer.

There are various shades of gold dyes that are suitable for use in the reflector according to the invention. A preferred shade is identified as product number 721 manufactured by ACA Corporation. This shade has the highest reflectivity for light in the 900 to 1100 nanometer infrared range and relatively low reflectivity (approximately 15%) in the ultraviolet range. Thus, reflectors incorporating this shade of gold material reduce the ultraviolet light damage to the photovoltaic panel. A reflector arranged at 45° relative to the photovoltaic panel and coated with gold dye product number 721 has a blue light reflectivity of approximately 53% which helps to minimize the heat generated on the panel.

The availability of different shades of gold dye for the reflector material has an important benefit. Because blue light produces 45% as much electric power as 900 nanometer light, blue light produces greater heating effects on the photovoltaic panel. The degree of ageing due to the higher heating obtained by including the blue light in the reflected power from the mirror is dependent to a good extent on the average temperature of the particular solar installation during summer. This factor is highly site dependent. With a cold climate, such as in northern portions of the northern hemisphere, the highest temperatures reached are not as great as in areas near the equator or in desert locations. For this reason, in colder climates, the best reflector surface would be one that simply minimizes UV light but has fairly high blue reflectivity, such as lighter shades of ACA Corporation product numbers 734 and 749 which have ultraviolet reflectivity of 28% to 17% and blue reflectivity of 68% to 53%, respectively. In hotter climates, middle-range tints would be suitable. For desert locations, the deepest gold tints would be preferred, such as shades of ACA Corporation product numbers 788 and 757 having ultraviolet reflectivity of 9% and blue reflectivity of 46% and 40%, respectively.

Testing of a gold tint reflector according to the invention in relation to other reflectors demonstrates the superior results obtained according to the invention. By way of example, testing was conducted as a function of the output of a flat photovoltaic panel in winter conditions. The panel output was measured under four conditions: (1) no reflector; (2) vertical thin glass reflector; (3) vertical coated composite backed aluminum reflector with no tinting; and (4) vertical coated composite backed aluminum reflector with ACA Corporation 721 gold tint.

The silicon photovoltaic-weighted apparent intensity of light striking the photovoltaic panel was measured as a function of the short circuit current in milliamperes (mA). The initial short circuit current was 57.6 mA. With the vertical thin glass reflector, short circuit current increased to 97.8 mA, indicating an increase of apparent light intensity of 70%. Comparing the output with the coated composite backed aluminum mirror without tinting to the vertical thin glass reflector, the relative light intensity with the coated aluminum reflector was 93.3 mA, indicating that the coated aluminum mirror had a reflectivity that was 95% of the value with the thin glass mirror when weighted by silicon response. Using a vertical coated composite backed aluminum reflector including ACA gold tint type 721, light intensity as measured with the solar cell was 88.2 mA, indicating that this reflector provides a reflectance that was 90% of the value produced with the vertical thin glass reflector when a solar silicon weighted response is used.

Other testing shows that the blue light reflectivity of a reflector with the ACA 721 gold coating is 53% in comparison to blue light reflectivity of 94% for a vertical coated composite backed aluminum reflector with no tinting, both with respect to the thin glass reflector. In addition, the red laser light (650 nanometer) reflectivity of the aluminum reflector with ACA 721 gold coating and of the coated composite backed aluminum reflector with no tinting are both 88% with respect to the thin glass reflector. Compared with the vertical glass reflector, the power produced by the panel using the gold tinted aluminum reflector was increased by 70%.

Next, the output of the photovoltaic panel using a coated aluminum reflector on the composite substrate was compared with the output of the panel with the vertical thin glass reflector. The relative light intensity with the coated aluminum reflector was 95% of the value with the thin glass reflector. Switching to the 721 gold-tinted aluminum reflector, the light intensity as measured with the solar cell was 90% of the value produced with the thin glass reflector.

The reflectivity of the gold tint aluminum reflector was measured by the National Renewable Energy Laboratories (NREL) and found to have a reflectivity of 78% when weighted to the solar spectrum. Heating of the solar photovoltaic panel is assumed to be essentially equal for all wavelengths of light since the solar panel appears to be essentially black to most wavelengths. The 78% reflectivity value is the weighted NREL reflectivity. Accordingly, light reflected from the gold-tinted aluminum reflector appears to heat the panel by a factor of 78%, but it produces electric power as if it had a reflectivity of 90%. The inventive reflector thus demonstrates improved photovoltaic electric power output with a reduced heating effect.

As noted above, other tests show that the blue light reflectivity of an ACA 721 gold tinted aluminum reflector is 53% in comparison to the 94% reflectivity for the coated composite backed aluminum reflector with no tinting, both with respect to the thin glass mirror.

Other tests were performed to measure the ultraviolet reflectivity of the sample reflectors. The non-tinted coated aluminum panel coated has a 365 nm ultraviolet reflectivity that is nearly 90%. The gold-tinted ACA 721 aluminum reflector has an ultraviolet reflectivity of 13%. This is a ratio of 6.7.

The ultraviolet at 365 nm is damaging to encapsulants. Thus, the ACA 721 tinted aluminum reflector is expected to induce ultraviolet damage at a rate that is 6.7 times lower than the non-tinted aluminum reflector.

The gold tinted aluminum reflector according to the invention has a longer life than non-tinted aluminum reflectors. Using a Ci65 reflectivity test using accelerated ultraviolet light, a coated silver film reflector with no tinting under the mark REFLECTEC III exhibited a dramatic reduction in reflectivity after 6.7 months. In contrast, the gold tinted aluminum reflector according to the invention did not show any degradation using the same test. Similarly, using a WOM type ultraviolet test, there is also no degradation of the gold-tinted anodized aluminum material after 6.7 months of ultraviolet accelerated testing which indicates superior stability of the reflective surface even without any sol-gel or fluorocarbon overcoating on the surface.

One drawback of a pure polymer based substrate such as shown in FIGS. 3-6 is that the polymer such as polyethylene is unstable since polyethylene has a relatively low heat distortion temperature of 60° C. Thus, reflectors formed with a pure polymer core tend to sag over time. This may be overcome by providing a polymer core structure including a filler material such as wood or wood fibers to substantially increase the resistance to sag. Other suitable fillers include clay or glass fiber. However, because wood is fairly inexpensive, wood fillers are particularly suitable. The wood fibers strengthen the substrate so that it is resistant to sag.

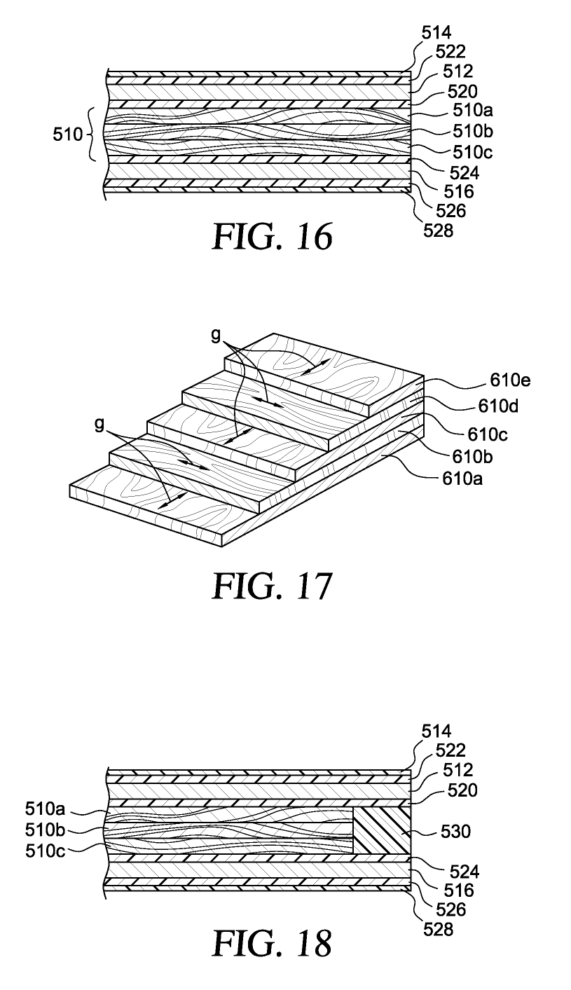

Referring now to FIGS. 16-18, a further embodiment of the reflector according to the invention will be described. In this embodiment, the substrate is formed of a plurality of layers of laminated wood sheets. As shown in FIG. 16, the reflector 506 includes a substrate 510 comprising three wooden layers 510a, 510b, and 510c which are formed as a laminated structure with adhesive layers (not shown) therebetween. On the upper surface of the substrate is provided an adhesion layer 520 having an aluminum reflector layer 512 connected therewith. As set forth above, the adhesion layer can be the result of treating the aluminum with a special chemical process such as acid etching or anodization to produce a highly porous structure that allows penetration of adhesives into the ports of the surface. The aluminum layer includes a coating 522 which is preferably a gold coating such as in the embodiment of FIGS. 3-6 which is visibly reflecting and ultraviolet absorbing. A protective coating layer 514 is provided on the color coating. The protective coating is preferably a silicate coating or a titanium oxide/silicon monoxide overcoat.

A similar reflector layer is provided on the lower surface of the substrate of FIG. 16. Thus, an adhesion layer 524 is provided to connect an aluminum layer 516 with the substrate. The aluminum reflector layer includes a color coating 526, preferably gold, and a protective coating layer 528. Thus, the reflector of FIG. 16 is reversible in that both the upper and lower surfaces have reflector layers which can be used to direct sunlight against a photovoltaic panel. As one surface degrades over time from exposure to sunlight, the reflector may be reversed so that the other surface thereof is used as the sunlight reflector. This effectively doubles the life of the reflector.

While the substrate of FIG. 16 is shown having 3 wood layers, any suitable number of layers may be provided. In FIG. 17 is shown a substrate having five layers 610a-e. The greater the number of layers, the stiffer the substrate becomes. For multi-layer wood substrates, it is preferable that the grain in each layer alternate in direction in successive adjacent layers. Thus for example in FIG. 17, the grain (represented by the arrows g) in layers 610a, 610c and 610e extends in one direction while the grain in layers 610b and 610d extends in a direction generally normal to the direction of the intervening layers. Any suitable hardwood may be used for the wood substrate. One such wood is maple.

Testing has shown that a reflector having a core substrate of raw polypropylene has a heat deflection temperature of 55° C. By adding wood flour to the composition of the polypropylene, the additive increases the heat deflection temperature of polypropylene substantially. Maple wood flour has the greatest effect, with the optimum improvement occurring at a wood flour loading of 50%. The resulting heat deflection temperature increases to 111° C. At 50% maple flour loading, the modulus of elasticity is also improved substantially from 1 to 4.16 gigapascals.

Comparing the heat deflection temperature of the 50% maple wood flour loaded polypropylene which is 111° C., the heat distortion temperature is 19 Degrees lower than polycarbonate plastic, which has a heat deflection temperature of 135° C. and 26 degrees higher than acrylic whose heat deflection temperature is 85° C.

In comparison to the wood flour filled polypropylene, wood panel material such as shown in FIGS. 16 has considerably better mechanical features. The glass transition temperature of wood is typically on the order of 160 to 170° C., substantially higher than the wood flour reinforced plastic composite core. The use of a wood panel, rather than a wood flour-polymer composite, allows the deliberate and controlled orientation of the fibers in the wood in the direction where the strength is needed. It is not possible to orient the fibers in a wood flour-polymer composite.

In the embodiment of FIG. 16, the edges of the reflector are exposed to water ingress which would severely limit the life of a pure wood-based composite panel. Referring to FIG. 18, a solution to this problem is provided in the form of an edge seal 530 which extends around the periphery of the reflector. The seal is preferably formed of a solid polymer such as a resin or polyethylene which substantial water resistance.

While the preferred forms and embodiments of the invention have been illustrated and described, it will be apparent to those of ordinary skill in the art that various changes and modifications may be made without deviating from the inventive concepts set forth above.

What is claimed is:

1. A reflector for a photovoltaic solar power generator, comprising
(a) a substrate having upper and lower surfaces; and
(b) a first layer of reflective material arranged on an upper surface of said substrate, said first layer of reflective material being coated with a color material which is stable to ultraviolet light.

2. A reflector as defined in claim 1, wherein said reflective material comprises metal.

3. A reflector as defined in claim 2, wherein said reflective material comprises aluminum.

4. A reflector as defined in claim 3, wherein said color material comprises a gold color dye, whereby said reflector has a reflectivity which is high for long wave, near infra red, and red to green light, moderate for blue light, and low for ultraviolet light.

5. A reflector as defined in claim 4, and further comprising a protective coating connected with said first layer of aluminum.

6. A reflector as defined in claim 5, and further comprising a second layer of reflective aluminum applied to the lower surface of said substrate.

7. A reflector as defined in claim 6, wherein said substrate is formed of a polymer material.

8. A reflector as defined in claim 7, and further comprising a layer of corrugated metal between said substrate and said second layer of reflective aluminum.

9. A reflector as defined in claim 5, wherein said coating comprises one of a sol-gel overcoat and a fluorocarbon overcoat.

10. A reflector as defined in claim 4, wherein said first layer of aluminum is anodized and dyed by one of ferric ammonium oxalate and ferric sodium oxalate.

11. A reflector as defined in claim 3, wherein said color material is applied to said first layer of aluminum by plasma vapor deposition to produce a gold tint, whereby said reflector has a reflectivity which is high for long wave, near infra red, and red to green light, moderate for blue light, and low for ultraviolet light.

12. A reflector as defined in claim 1, wherein said reflective material comprises a synthetic plastic film and said color material is doped on said film to absorb ultraviolet light and at least a portion of blue light.

13. A reflector as defined in claim 6, wherein said second layer of reflective aluminum is coated with a color material which is stable to ultraviolet light.

14. A reflector as defined in claim 13, wherein said color material coated on said second layer of reflective aluminum comprises a gold color dye, whereby said reflector is reversible.

15. A reflector as defined in claim 1, wherein said substrate is formed of a wood material to prevent sagging of said reflector.

16. A reflector as defined in claim 15, wherein said substrate is formed of a polymer material containing a wood filler material.

17. A reflector as defined in claim 15, wherein said substrate is formed of a plurality of laminated sheets of wood.

18. A reflector as defined in claim 17, wherein said sheets of wood are arranged so that a grain direction in a sheet alternates in a normal direction to the grain direction of an adjacent sheet to increase the strength and rigidity of the reflector.

19. A reflector as defined in claim 15, and further comprising a second layer of reflective material coated with a color material which is stable to ultraviolet light, whereby the reflector is reversible.

20. A reflector as defined in claim 19, wherein said first and second layers of reflective material comprise aluminum and said color material comprises a gold color dye, whereby said reflector has a reflectivity which is high for long wave, near infra red and red to green light, moderate for blue light, and low for ultraviolet light.

21. A reflector as defined in claim 20, and further comprising a protective coating connected with said first and second layers of aluminum.

22. A reflector as defined in claim 19, and further comprising a seal connected with said reflector along an edge thereof to prevent moisture from contacting said substrate.

23. A photovoltaic power generator, comprising
(a) a photovoltaic panel for converting sunlight into electricity, said panel being positioned relative to the sun; and
(b) a reflector arranged adjacent to said photovoltaic panel for directing sunlight onto said panel, said reflector comprising
(1) a substrate; and
(2) a first layer of reflective material arranged on an upper surface of said substrate, said first layer of reflective material being coated with a color material which is stable to ultraviolet light.

24. A photovoltaic power generator as defined in claim 23, wherein said reflective material comprises a synthetic plastic film and said color material is doped on said film to absorb ultraviolet light and at least a portion of blue light.

25. A photovoltaic power generator as defined in claim 23, wherein said reflective material comprises a metal.

26. A photovoltaic power generator as defined in claim 25, wherein said reflective material comprises aluminum.

27. A photovoltaic power generator as defined in claim 26, wherein said color material comprises a dye having a gold color, whereby said reflector has a reflectivity which is high for long wave, near infra red, and red to green light, moderate for blue light, and low for ultraviolet light.

28. A photovoltaic power generator as defined in claim 27, wherein said first layer of aluminum is anodized and dyed by one of ferric ammonium oxalate and ferric sodium oxalate.

29. A photovoltaic power generator as defined in claim 26, wherein said color material is applied to said first layer of aluminum by plasma vapor deposition to produce a gold tint, whereby said reflector has a reflectivity which is high for long wave, near infra red, and red to green light, moderate for blue light, and low for ultraviolet light.

30. A photovoltaic power generator as defined in claim 23, wherein said reflector has a concave configuration.

31. A photovoltaic power generator as defined in claim 30, and further comprising a support for adjustably mounting said reflector in spaced relation adjacent to said photovoltaic panel, whereby the angle of said reflector relative to said panel may be adjusted in accordance with the angle of incidence of sunlight onto said reflector and said photovoltaic panel.

32. A photovoltaic power generator as defined in claim 31, wherein said photovoltaic panel is positioned relative to a north-south axis.

33. A photovoltaic power generator as defined in claim 30, and further comprising a second layer of reflective aluminum applied to the lower surface of said reflector substrate, said second layer of reflective aluminum being coated with a gold color dye.

34. A photovoltaic power generator as defined in claim 33, and further comprising a protective coating connected with said first and second layers of aluminum of said reflector.

35. A photovoltaic power generator as defined in claim 34, wherein said reflector substrate comprises a polymer material.

36. A photovoltaic power generator as defined in claim 34, wherein said reflector substrate is formed of a wood material to prevent sagging of said reflector.

37. A reflector as defined in claim 36, wherein said substrate is formed of a polymer material containing a wood filler material.

38. A reflector as defined in claim 36, wherein said substrate is formed of a plurality of laminated sheets of wood.

39. A reflector as defined in claim 38, wherein said sheets of wood are arranged so that a grain direction in a sheet alternates in a normal direction to the grain direction of an adjacent sheet to increase the strength and rigidity of the reflector.

40. A reflector as defined in claim 39, and further comprising a seal connected with said reflector along an edge thereof to prevent moisture from contacting said substrate.

41. A photovoltaic power generator as defined in claim 34, wherein a plurality of photovoltaic panels each having an adjacent reflector are arranged in series.

42. A photovoltaic power generator as defined in claim 33, wherein said gold colored dye is one of a variety of shades, with a darker shade being provided on reflectors to be used in locations nearer the equator and lighter shades being provided on reflectors to be used in locations toward the poles.
